(19) United States
(12) Patent Application Publication
(10) Pub. No.: US 2007/0018710 A1
(43) Pub. Date: Jan. 25, 2007

(54) Level shifter circuit of semiconductor memory device

(75) Inventors: Yun-jeong Choi, Suwon-si (KR); Young-sun Min, Seoul (KR); Young-min Jang, Seoul (KR)

Correspondence Address: MILLS & ONELLO LLP, ELEVEN BEACON STREET, SUITE 605, BOSTON, MA, 02108, US

(73) Assignee: Samsung Electronics Co. Ltd.

(21) Appl. No.: 11/416,437

(22) Filed: May 2, 2006

(30) Foreign Application Priority Data
Jul. 25, 2005 (KR) 10-2005-0067446

(51) Int. Cl. H03L 5/00

(52) U.S. Cl. 327/333

(57) ABSTRACT

A level shifter circuit of a semiconductor memory device prevents a leakage current from being generated in a deep power down mode. The level shifter circuit comprises: a first NMOS transistor connected between a first node and a ground voltage terminal, wherein an input signal, which has a voltage level that is one of the ground voltage and a first power supply voltage, is input to a gate of the first NMOS transistor; a second NMOS transistor connected between a second node and the ground voltage terminal, wherein an inverted signal of the input signal is input to a gate of the second NMOS transistor; a first PMOS transistor which is connected between the first node and a second power supply voltage terminal and has a gate connected to the second node; a second PMOS transistor which is connected between the second node and the second power supply voltage terminal and has a gate connected to the first node; and a third NMOS transistor which has a drain connected to one of the first node and the second node and a gate connected to the other one of the first node and the second node and which maintains the first node and the second node each at one of two high and low logic levels when operating in a reduced power mode.

### RELATED APPLICATIONS

This application claims priority to Korean Patent Application No. 10-2005-0067446 filed on Jul. 25, 2005, in the Korean Intellectual Property Office, the disclosure of which is incorporated herein by reference in its entirety.

### BACKGROUND OF THE INVENTION

1. Field of the Invention

The present invention relates to a level shifter circuit of a semiconductor memory device, and more particularly, to a level shifter circuit of a semiconductor memory device, which is capable of preventing a leakage current from being generated during operations in a deep power down mode.

2. Description of the Related Art

With the continuing demand for highly integrated and high storage capacity semiconductor memory devices, the device design rule continues to decrease so that device integration can be increased. Since high ly integrated and high storage capacity semiconductor memory devices generally have high power consumption, much effort has been made to reduce such power consumption. For example, to reduce power consumption, a semiconductor memory device can be caused to enter a deep power down (DPD) mode by turning off an internal voltage used in the semiconductor memory device when the semiconductor memory device does not operate in an active mode.

Semiconductor memory devices commonly include a level shifter for converting a signal that has a logic level that transitions between an internal voltage level and a ground voltage level into a signal that has a logic level that transitions between another internal voltage level or an external logic level and a ground voltage level. However, for the level shifter that converts a signal at the internal voltage level into a signal at the external voltage level, since the signal at the internal voltage level is turned off when a semiconductor memory is in a DPD mode, internal devices that operate in response to the signal at the internal voltage level can malfunction. As a result, signals of the level shifter may be placed in a floating state. If the signals are in a floating state, a leakage current can be generated by the output signals at output ends of the level shifter, resulting in an increase in the power consumption of the semiconductor memory device.

### SUMMARY OF THE INVENTION

The present invention provides a level shifter circuit of a semiconductor memory device capable of preventing a leakage current from being generated during operation in a deep power down mode.

In one aspect, the present invention is directed to a level shifter circuit comprising: a first NMOS transistor connected between a first node and a ground voltage terminal, wherein an input signal, which has a voltage level that is one of the ground voltage and a first power supply voltage, is input to a gate of the first NMOS transistor; a second NMOS transistor connected between a second node and the ground voltage terminal, wherein an inverted signal of the input signal is input to a gate of the second NMOS transistor; a first PMOS transistor which is connected between the first node and a second power supply voltage terminal and has a gate connected to the second node; a second PMOS transistor which is connected between the second node and the second power supply voltage terminal and has a gate connected to the first node; and a third NMOS transistor which has a drain connected to one of the first node and the second node and a gate connected to the other one of the first node and the second node and which maintains the first node and the second node each at one of high and low logic levels when operating in a reduced power mode.

In one embodiment, the first power supply voltage is an internal power supply voltage.

In another embodiment, the second power supply voltage is an external power supply voltage.

In another embodiment, one of the first node and the second node connected to the drain of the third NMOS transistor transitions to a low logic level when operating in a standby mode.

In another embodiment, the third NMOS transistor has a smaller active region than the active regions of the first NMOS transistor and the second NMOS transistor.

In another embodiment, the level shifter circuit further comprises an output end connected to the first node or the second node.

In another embodiment, the output end is a CMOS inverter that operates between the second power supply voltage and the ground voltage.

In another embodiment, the reduced power mode is a deep power down mode.

In another aspect, the present invention is directed to a level shifter circuit of a semiconductor memory device comprising: a first NMOS transistor connected between a first node and a ground voltage terminal, wherein an input signal, which has a voltage level that is one of the ground voltage and a first power supply voltage is input to a gate of the first NMOS transistor; a second NMOS transistor connected between a second node and the ground voltage terminal, wherein an inverted signal of the input signal is input into a gate of the second NMOS transistor; a first PMOS transistor which is connected between the first node and a second power supply voltage terminal and has a gate connected to the second node; a second PMOS transistor which is connected between the second node and the second power supply voltage terminal and has a gate connected to the first node; and a third NMOS transistor, which has a drain connected to the first node and a gate connected to the second node, and a fourth NMOS transistor, which has a drain connected to the second node and has a gate connected to the first node, wherein the third and fourth NMOS transistors maintain the first node and the second node each at one of high and low logic levels when operating in a reduced power mode.

In one embodiment, the first power supply voltage is an internal power supply voltage.

In another embodiment, the second power supply voltage is an external power supply voltage.

In another embodiment, one of the first node and the second node connected to the drain of the third NMOS transistor transitions to a low logic level when operating in a standby mode.

In another embodiment, the level shifter circuit further comprises an output end connected to the first node or the second node.

In another embodiment, the output end is a CMOS inverter that operates between the second power supply voltage and the ground voltage.

In another embodiment, the reduced power mode is a deep power down mode.

### BRIEF DESCRIPTION OF THE DRAWINGS

The foregoing and other objects, features and advantages of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention. In the drawings:

FIG. 1 is a block diagram of a semiconductor memory device including level shifters according to an embodiment of the present invention;

FIG. 2 is a circuit diagram of a first level shifter of FIG. 1;

FIG. 3 is a circuit diagram of a second level shifter of FIG. 1 according to a first embodiment of the present invention;

FIG. 4 is a circuit diagram of the second level shifter of FIG. 1 according to a second embodiment of the present invention; and

FIG. 5 is a circuit diagram of the second level shifter of FIG. 1 according to a third embodiment of the present invention.

### DETAILED DESCRIPTION OF EMBODIMENTS OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Like numbers refer to like elements throughout the specification.

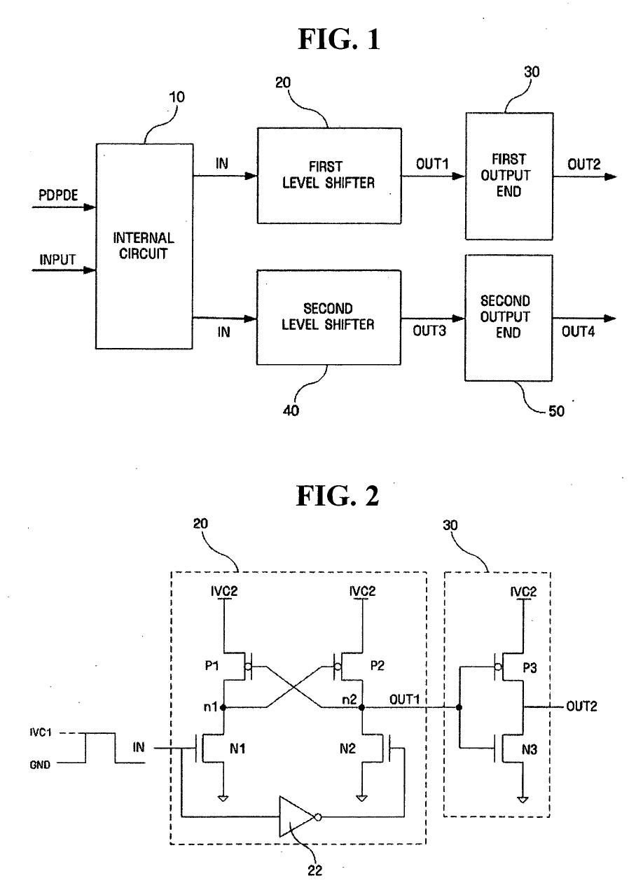

Hereinafter, the configuration and operation of a semiconductor memory device according to an embodiment of the present invention will be described with reference to FIG. 1. FIG. 1 is a block diagram of a semiconductor memory device including level shifters according to an embodiment of the present invention.

As shown in FIG. 1, a semiconductor memory device according to an embodiment of the present invention includes an internal circuit 10, a first level shifter 20, a first output end 30, a second level shifter 40, and a second output end 50.

The internal circuit 10 is controlled in response to a deep power down signal PDPDE and an input signal INPUT and supplies an input signal IN, which has logic levels that alternate between a ground voltage GND and a first internal power supply voltage IVC1, to the first level shifter 20 and the second level shifter 40. When the deep power down signal PDPDE is enabled, the semiconductor memory device operates in a deep power down (DPD) mode to reduce its power consumption, and thus, the input signal IN supplied to the first level shifter 20 and the second level shifter 40 is interrupted.

The first level shifter 20 is supplied with the input signal IN by the internal circuit 10 and converts the input signal IN into an output signal OUT1, which has logic levels that alternate between the ground voltage GND and a second internal power supply voltage IVC2. The output signal OUT1 output from the first level shifter 20 is supplied to the first output end 30.

The second level shifter 40 is supplied with the input signal IN by the internal circuit 10 and converts the input signal IN into an output signal OUT3, which has logic levels that alternate between the ground voltage GND and an external power supply voltage EVC. When operating in the DPD mode, the second level shifter 40 holds the output signal OUT3 output in a standby mode immediately preceding the DPD mode in a latched state. In this manner, the output signal OUT3 output from the second level shifter 40 is prevented from floating. When the semiconductor memory device operates in the DPD mode, the second level shifter 40 outputs the output signal OUT3 at a specific logic level and supplies the same to the second output end 50. Since the output signal OUT3 input to the second output end 50 has a specific logic level during operation in the DPD mode, leakage current is mitigated or eliminated at the second output end 50.

Hereinafter, the configurations and operations of the first level shifter 20 and the second level shifter 40 will be described in detail with reference to FIGS. 2 through 5. FIG. 2 is a circuit diagram of the first level shifter of FIG. 1.

As shown in FIG. 2, the first level shifter 20 for converting the input signal IN, which has logic levels that alternate between the ground voltage GND and the first internal power supply voltage IVC1, into the output signal OUT1, which has logic levels that alternate between the ground voltage GND and the second internal power supply voltage IVC2, includes two PMOS transistors P1 and P2, two NMOS transistors N1 and N2, and one inverter 22. The first PMOS transistor P1 and the first NMOS transistor N1 are connected in series between the second internal power supply voltage IVC2 and the ground voltage GND. The second PMOS transistor P2 and the second NMOS transistor N2 are also connected in series between the second internal power supply voltage IVC2 and the ground voltage GND. The second internal power supply voltage IVC2 is input to the sources of the first PMOS transistor P1 and the second PMOS transistor P2 of the first level shifter 20. The gates and drains of the first PMOS transistor P1 and the second PMOS transistor P2 are cross-connected as shown. In other words, the first PMOS transistor P1 and the second PMOS transistor P2 form a cross coupled structure.

The input signal IN output by the internal circuit (10 of FIG. 1) is input to a gate of the first NMOS transistor N1 and an input signal IN inverted by the inverter 22 is input to a gate of the second NMOS transistor N2. The inverter 22 operates at the first internal power supply voltage IVC1. The ground voltage GND is input to sources of the first NMOS transistor N1 and the second NMOS transistor N2. A drain of the first NMOS transistor N1, a drain of the first PMOS transistor P1, and a gate of the second PMOS transistor P2 are commonly connected to a first node n1. A drain of the second NMOS transistor N2, a drain of the second PMOS transistor P2, and a gate of the first PMOS transistor P2 are commonly connected to a second node n2. The second node n2 provides the output signal OUT1, and is connected to an input of the first output end 30.

The first output end 30 is in the form of a CMOS inverter and includes a third PMOS transistor P3 and a third NMOS transistor N3 connected in series between the second internal power supply voltage IVC2 and the ground voltage GND. The output signal OUTI output from the first level shifter 20 is input to a gate of the third PMOS transistor P3, the second internal power supply voltage IVC2 is input to a source of the third PMOS transistor P3, and a drain of the third NMOS transistor N3 is connected to a drain of the third PMOS transistor P3. The output signal OUT1 output from the first level shifter 20 is also input to the gate of the third PMOS transistor P3 and the ground voltage GND is input to the source of the third PMOS transistor P3.

Next, the operation of the first level shifter 20 will be described. First, when the input signal IN supplied from the internal circuit (10 of FIG. 1) is at a low logic level, the first NMOS transistor N1 is turned off and the second NMOS transistor N2 is turned on. Thus, the second node n2 goes to a low logic level, the first PMOS transistor P1 is turned on, and thus the second internal power supply voltage IVC2 is supplied. As a result, the first node n1 goes to a high logic level. Thus, the second PMOS transistor P2 is turned off and a low logic level output signal OUT1 is supplied to the first output end 30 connected to the second node n2 of the first level shifter 20.

When the input signal IN input to the first level shifter 20 is at a high logic level, the first NMOS transistor N1 is turned on and the second NMOS transistor N2 is turned off. Thus, the first node n1 goes to a low logic level, the second PMOS transistor P2 is turned on, and thus the second internal power supply voltage IVC2 is supplied. As a result, the second node n2 goes to a high logic level. Thus, the first PMOS transistor P1 is turned off and a high logic level of the second internal power supply voltage IVC2 is input as the output signal OUT1 to the first output end 30 connected to the second node n2 of the first level shifter 20. Thus, the output signal OUT1, which has a logic level that alternates between the ground GND voltage level and the second internal power supply voltage level IVC2, is output from the second node n2 of the first level shifter 20.

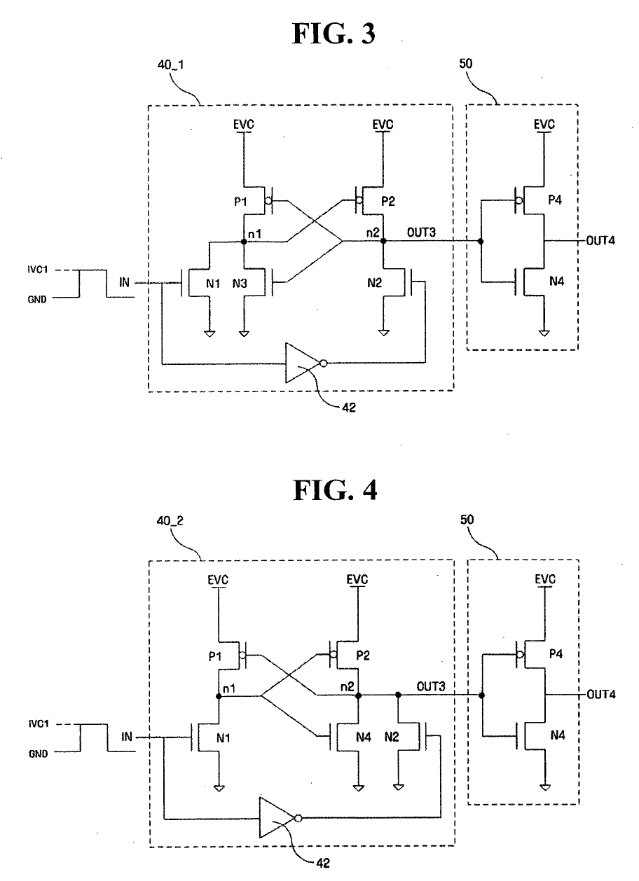

FIG. 3 is a circuit diagram of a second level shifter of FIG. 1 according to a first embodiment of the present invention. As shown in FIG. 3, a second level shifter 40_1 includes first and second PMOS transistors P1 and P2, first, second and third NMOS transistors N1, N2, and N3, and an inverter 42. The first NMOS transistor N1 is connected between a first node n1 and the ground voltage GND terminal. The input signal IN, which has a logic level that alternates between the ground voltage GND and the first internal power supply voltage IVC1, is applied to a gate of the first NMOS transistor N1. The second NMOS transistor N2 is connected between a second node n2 and the ground voltage GND terminal. The input signal IN, as inverted by the inverter 42, is input to a gate of the second NMOS transistor N2. The inverter 42 operates at an internal power supply voltage. The first PMOS transistor P1 is connected between the first node n1 and the external power supply voltage EVC terminal and the second node n2 is connected to a gate of the first PMOS transistor P1. The second PMOS transistor P2 is connected between the second node n2 and the external power supply voltage EVC terminal and the first node n1 is connected to a gate of the second PMOS transistor P2.

A drain of the third NMOS transistor N3 is connected to one of the first node n1 and the second node n2 and a gate of the third NMOS transistor N3 is connected to the other one of the first node n1 and the second node n2. At this time, when the circuit operates in a standby mode immediately preceding the DPD mode, the drain of the third NMOS transistor N3 is connected to the first node n1 at a low logic level and the gate of the third NMOS transistor N3 is connected to the second node n2. Thus, the third NMOS transistor N3 retains the first node n1 and the second node n2 at specific logic levels when operating in the DPD mode.

The second node n2 of the second level shifter 40_1 is connected to an input of the second output end 50. The second output end 50 is in the form of a CMOS inverter and includes a fourth PMOS transistor P4 and a fourth NMOS transistor N4. The output signal OUT3 output by the second level shifter 40_1 is input to a gate of the fourth PMOS transistor P4, the external power supply voltage EVC is input to a source of the fourth PMOS transistor P4, and a drain of the fourth NMOS transistor N4 is connected to a drain of the fourth PMOS transistor P4. The output signal OUT3 output by the second level shifter 40_1 is input to a gate of the fourth NMOS transistor N4 and the ground voltage GND is input to a source of the fourth NMOS transistor N4.

The operation of the second level shifter 40_1 of FIG. 3 will now be described. First, when the deep power down signal PDPDE of the semiconductor memory device is disabled, the input signal IN, which has a logic level that alternates between the ground voltage GND and the first internal power supply voltage IVC1, is input to the second level shifter 40_1. At this time, when the input signal IN is at a high logic level, the first NMOS transistor N1 is turned on and the second NMOS transistor N2 is turned off. Thus, the first node n1 goes to a low logic level, the second PMOS transistor P2 is turned on, and thus the external power supply voltage EVC is supplied. As a result, the second node n2 goes to a high logic level. Thus, the first PMOS transistor P1 is turned off and the first NMOS transistor N1 is turned on. The first node n1 goes to a low logic level, as driven by not only the first NMOS transistor N1 but also by the third NMOS transistor N3. The second level shifter 40_1 outputs the output signal OUT3 at a high logic level from the second node n2 to the second output end 50.

When the input signal IN is at a low logic level, the first NMOS transistor N1 is turned off and the second NMOS transistor N2 is turned on. Thus, the second node n2 goes to a low logic level, the first PMOS transistor P1 is turned on, and the external power supply voltage EVC is supplied. As a result, the first node n1 goes to a high logic level and the second PMOS transistor P2 is turned off.

Therefore, when the deep power down signal PDPDE is disabled, the second level shifter 40_1 converts the input signal IN, which has a logic level that alternates between the ground voltage GND and the first internal power supply voltage IVC1, into the output signal OUT3, which has a logic level that alternates the ground voltage GND and the external power supply voltage EVC.

Next, when the deep power down signal PDPDE of the semiconductor memory device becomes enabled, the input signal IN supplied to the second level shifter 40_1 is interrupted. Thus, the input signal IN at a low logic level is input to the second level shifter 40_1. and the inverter 42 operating at the first internal power supply voltage IVC1 supplies the input signal IN at a low logic level to the gate of the second NMOS transistor N2 without an inverting operation.

When the deep power down signal PDPDE is enabled, the input signal IN transitions from a high logic level to a low logic level. Once the input signal IN transitions to a low logic level, the inverter 42 does not operate and the first NMOS transistor N1 and the second NMOS transistor N2 are turned off. At this time, the first node n1 and the second node n2 are not placed in a floating state, but rather are latched by the third NMOS transistor N3 to the same logic levels as those present immediately before the circuit entered the DPD mode. Thus, in this example, the first node n1 is maintained at a low logic level and the second node n2 is maintained at a high logic level. As a result, the output signal OUT3 of the second level shifter 40_1 is maintained at a specific logic level, thereby preventing a leakage current from being generated at the second output end 50.

FIG. 4 is a circuit diagram of a second level shifter of FIG. 1 according to a second embodiment of the present invention. As shown in FIG. 4, a second level shifter 40_2 uses the fourth NMOS transistor N4 instead of the third NMOS transistor N3 shown in FIG. 3.

A drain of the fourth NMOS transistor N4 is connected to one of the first node n1 and the second node n2 and a gate of the fourth NMOS transistor N4 is connected to the other one of the first node n1 and the second node n2. When operating in a standby mode immediately prior to operation in the DPD mode, the drain of the fourth NMOS transistor N4 is connected to the second node n2 at a low logic level and the gate of the fourth NMOS transistor N4 is connected to the first node n1. Thus, the fourth NMOS transistor N4 maintains the first node n1 and the second node n2 at specific logic levels when operating in the DPD mode.

The latching operation of the second level shifter 40_2 of FIG. 4 is now described as follows. When the deep power down signal PDPDE is disabled, the second level shifter 40_2 of FIG. 4 operates in the same manner as the second level shifter 40_2 of FIG. 3. When operating in the standby mode, the input signal IN at a low logic level is input to the second level shifter 40_2. The deep power down signal PDPDE is then enabled, and thus the semiconductor memory device enters the DPD mode. As a result, immediately before the. semiconductor memory device enters the DPD mode, the second NMOS transistor N2 and the third NMOS transistor N3 of the second level shifter 40_2 are turned on, and thus the second node n2 goes to a low logic level. In addition, the first PMOS transistor P1 is turned on, the external power supply voltage EVC is supplied, and thus the first node n1 goes to a high logic level. If the semiconductor memory device enters the DPD mode in this state, the first NMOS transistor N1 and the second NMOS transistor N2 are turned off. At this time, the second node n2 is maintained at a low logic level by the third NMOS transistor N3 such that the second node n2 does not float, and the first node n1 is maintained at a high logic level. Thus, when transitioning to the DPD mode, the logic levels of the first node n1 and the second node n2 of the second level shifter 40_2 that existed immediately prior to activation of the DPD mode are latched, and thus they are not in a floating state.

As shown in FIGS. 3 and 4, it is preferable that the third NMOS transistor N3 and the fourth NMOS transistor N4 that operate to latch the output signal OUT3 of the second level shifters 40_1 and 40_2 when operating in the DPD mode have smaller active regions than those of the first NMOS transistor N1 and the second NMOS transistor N2, in order to prevent a current flowing through the third NMOS transistor N3 and the fourth NMOS transistor N4 from increasing when the deep power down signal PDPDE is disabled.

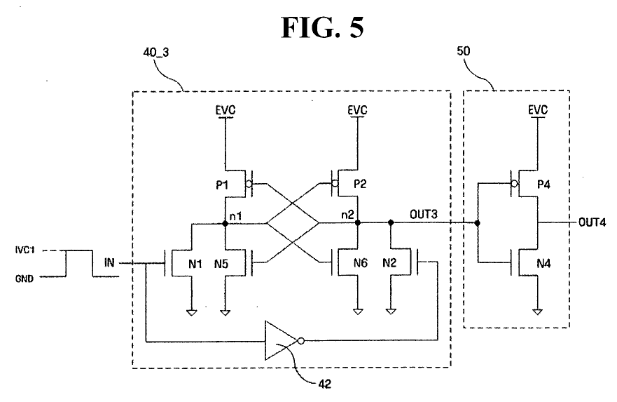

FIG. 5 is a circuit diagram of a second level shifter of FIG. 1 according to a third embodiment of the present invention. By using the second level shifter 40_3 of FIG. 5, when operating in the DPD mode, the output signal OUT3 can be latched in the DPD mode as the output signal OUT3 that existed immediately prior to operation the DPD mode, regardless of the state of the input signal IN immediately prior to the DPD mode.

More specifically, as shown in FIG. 5, the second level shifter 40_3 includes two PMOS transistors P1 and P2, four NMOS transistors N1, N2, N5, and N6, and an inverter 42. The first NMOS transistor N1 is connected between the first node n1 and the ground voltage GND. The input signal IN, which has a logic level that alternates between the ground voltage GND and the first internal power supply voltage IVC1, is input to a gate of the first NMOS transistor N1. The second NMOS transistor N2 is connected to the second node n2 and the ground voltage GND. The input signal IN, as inverted by the inverter 42, is input to a gate of the second NMOS transistor N2. T he inverter 42 operates at an internal power supply voltage. The first PMOS transistor P1 is connected between the first node n1 and the external power supply voltage EVC and a gate of the first PMOS transistor P1 is connected to the second node n2. The second PMOS transistor P2 is connected between the second node n2 and the external power supply voltage EVC terminal and a gate of the second PMOS transistor P2 is connected to the first node n1.

A drain of the fifth NMOS transistor N5 is connected to the first node n1 and a gate of the fifth NMOS transistor N5 is connected to the second node n2. A drain of the sixth NMOS transistor N6 is connected to the second node n2 and a gate of the sixth NMOS transistor N6 is connected to the first node n1. The fifth NMOS transistor N5 and the sixth NMOS transistor N6 maintain the first node n1 and the second node n2 at specific logic levels when operating in the DPD mode, to prevent the nodes from being in a floating state.

The second node n2 of the second level shifter 40_3 provides output signal OUT3 and is connected to an input of the second output end 50. The second output end 50 is in the form of a CMOS inverter and is the same as the second output end 50 connected to the second node n2 of the second level shifter 40_3 of FIGS. 3 and 4.

The operation of the second level shifter 40_3 of FIG. 5 will now be described. First, if the input signal IN at a high logic level is input when the deep power down signal PDPDE is disabled, the first NMOS transistor N1 is turned on and the first node n1 goes to a low logic level. As a result, the second PMOS transistor P2 is turned on, the external power supply voltage EVC is supplied, and thus the second node n2 goes to a high logic level. Thus, the first node n1 is driven to a low logic level in addition by the fifth NMOS transistor N5. The second level shifter 40_3 supplies the output signal OUT3 at a high logic level to the second output end 50.

In this state, if the deep power down signal PDPDE is enabled and the semiconductor memory device enters the DPD mode, the input signal IN goes to a low logic level and the inverter 42 does not operate. As a result, the first NMOS transistor N1 and the second NMOS transistor N2 are turned off. At this time, the logic level states of the first node n1 and the second node n2 that existed immediately prior to the DPD mode are latched by the third NMOS transistor N3.

If the input signal IN at a low logic level is input at the time when the deep power down signal PDPDE is enabled, the second NMOS transistor N2 is turned on and the second node n2 goes to a low logic level. As a result, the first PMOS transistor P1 is turned on, the external power supply voltage EVC is supplied, and thus the first node n1 goes to a high logic level. Thus, the second node n2 is driven to a low logic level in addition by the sixth NMOS transistor N6. The second level shifter 40_3 supplies the output signal OUT3 at a low logic level to the second output end 50.

In this state, if the deep power down signal PDPDE is enabled and the semiconductor memory device enters the DPD mode, the inverter 42 does not operate and the first NMOS transistor N1 and the second NMOS transistor N2 are turned off. At this time, logic level states of the first node n1 and the second node n2 that existed immediately prior to the DPD mode are latched by the sixth NMOS transistor N6.

It is preferable that the fifth NMOS transistor N5 and the sixth NMOS transistor N6 that latch the output signal OUT3 of the second level shifter 40_3 in the DPD mode have smaller active regions than those of the first NMOS transistor N1 and the second NMOS transistor N2, in order to prevent a current flowing through the fifth NMOS transistor N5 and the sixth NMOS transistor N6 from increasing when the deep power down signal PDPDE is disabled.

When the semiconductor memory device enters the DPD mode, the second level shifter 40_3 can prevent the output signal OUT3 from floating by latching the state of the output signal OUT3 to a specific logic level. Thus, a leakage current is prevented from being generated at the second output end 50 to which the output signal OUT3 of the second level shifter 40_3 is input.

As described above, according to the present invention, a level shifter that converts an input signal, which has a logic level that alternates between a ground voltage and an internal power supply voltage, into an output signal, which has a logic level that alternates between the ground voltage and an external power supply voltage, in an active mode can latch its output signal when a semiconductor memory device enters a DPD mode. In this manner, an input signal of an output end connected to the level shifter circuit is prevented from floating. Thus, it is possible to prevent a leakage current from being generated at the output end connected to the level shifter circuit. Accordingly, it is possible to reduce power consumption of the semiconductor memory device when operating in the DPD mode.

While this invention has been particularly shown and described with references to preferred embodiments thereof, it will be understood by those skilled in the art that various changes in form and details may be made herein without departing from the spirit and scope of the invention as defined by the appended claims.

What is claimed is:

1. A level shifter circuit of a semiconductor memory device comprising:
a first NMOS transistor connected between a first node and a ground voltage terminal, wherein an input signal, which has a voltage level that is one of the ground voltage and a first power supply voltage, is input to a gate of the first NMOS transistor;
a second NMOS transistor connected between a second node and the ground voltage terminal, wherein an inverted signal of the input signal is input to a gate of the second NMOS transistor;
a first PMOS transistor which is connected between the first node and a second power supply voltage terminal and has a gate connected to the second node;
a second PMOS transistor which is connected between the second node and the second power supply voltage terminal and has a gate connected to the first node; and
a third NMOS transistor which has a drain connected to one of the first node and the second node and a gate connected to the other one of the first node and the second node and which maintains the first node and the second node each at one of high and low logic levels when operating in a reduced power mode.

2. The level shifter circuit of claim 1, wherein the first power supply voltage is an internal power supply voltage.

3. The level shifter circuit of claim 1, wherein the second power supply voltage is an external power supply voltage.

4. The level shifter circuit of claim 1, wherein one of the first node and the second node connected to the drain of the third NMOS transistor transitions to a low logic level when operating in a standby mode.

5. The level shifter circuit of claim 1, wherein the third NMOS transistor has a smaller active region than the active regions of the first NMOS transistor and the second NMOS transistor.

6. The level shifter circuit of claim 1, further comprising an output end connected to the first node or the second node.

7. The level shifter circuit of claim 6, wherein the output end is a CMOS inverter that operates between the second power supply voltage and the ground voltage.

8. The level shifter circuit of claim 1, wherein the reduced power mode is a deep power down mode.

9. A level shifter circuit of a semiconductor memory device comprising:
a first NMOS transistor connected between a first node and a ground voltage terminal, wherein an input signal, which has a voltage level that is one of the ground voltage and a first power supply voltage is input to a gate of the first NMOS transistor;
a second NMOS transistor connected between a second node and the ground voltage terminal, wherein an inverted signal of the input signal is input into a gate of the second NMOS transistor;
a first PMOS transistor which is connected between the first node and a second power supply voltage terminal and has a gate connected to the second node;
a second PMOS transistor which is connected between the second node and the second power supply voltage terminal and has a gate connected to the first node; and
a third NMOS transistor, which has a drain connected to the first node and a gate connected to the second node, and a fourth NMOS transistor, which has a drain connected to the second node and has a gate connected to the first node, wherein the third and fourth NMOS transistors maintain the first node and the second node each at one of high and low logic levels when operating in a reduced power mode.

10. The level shifter circuit of a semiconductor memory device of claim 9, wherein the first power supply voltage is an internal power supply voltage.

11. The level shifter circuit of a semiconductor memory device of claim 9, wherein the second power supply voltage is an external power supply voltage.

12. The level shifter circuit of a semiconductor memory device of claim 9, wherein one of the first node and the second node connected to the drain of the third NMOS transistor transitions to a low logic level when operating in a standby mode.

13. The level shifter circuit of a semiconductor memory device of claim 9, further comprising an output end connected to the first node or the second node.

14. The level shifter circuit of a semiconductor memory device of claim 13, wherein the output end is a CMOS inverter that operates between the second power supply voltage and the ground voltage.

15. The level shifter circuit of a semiconductor memory device of claim 9, wherein the reduced power mode is a deep power down mode.
